(19) United States
(12) Patent Application Publication
(10) Pub. No.: US 2023/0083995 A1
(43) Pub. Date: Mar. 16, 2023

(54) HEAT DISSIPATION ASSEMBLY AND ELECTRONIC DEVICE

(71) Applicants: Inventec (Pudong) Technology Corporation, Shanghai (CN); INVENTEC CORPORATION, Taipei (TW)

(72) Inventors: Yucheng Wang, Shanghai (CN); Shukang Han, Shanghai (CN)

(21) Appl. No.: 17/693,539

(22) Filed: Mar. 14, 2022

(30) Foreign Application Priority Data
Sep. 10, 2021 (CN) 202111062265.0

(51) Int. Cl. G06F 1/20; H05K 7/20; H01L 35/30; H01L 35/32

(52) U.S. Cl. CPC G06F 1/206; H05K 7/20218; H01L 35/30; H01L 35/32

(57) ABSTRACT

A heat dissipation assembly is configured to be thermally coupled to a heat source. The heat dissipation assembly includes a thermoelectric cooler and a heat dissipation component. The thermoelectric cooler has a cold surface and a hot surface. The cold surface faces away from the hot surface, and the cold surface is configured to be thermally coupled to the heat source. The heat dissipation component is thermally coupled to the hot surface of the thermoelectric cooler.

### CROSS-REFERENCE TO RELATED APPLICATIONS

This non-provisional application claims priority under 35 U.S.C. § 119(a) on Patent Application No(s). 202111062265.0 filed in China, on Sep. 10, 2021, the entire contents of which are hereby incorporated by reference.

### BACKGROUND OF THE INVENTION

### Technical Field of the Invention

The invention relates to an electronic device and a heat dissipation assembly, more particularly to an electronic device and a heat dissipation assembly including a thermoelectric cooler.

### Description of the Related Art

In general, a computer mainly includes a casing, a power supply, a motherboard, a central processing unit, a graphic processing unit, and an expansion card. The power supply and the motherboard are installed in the casing, and the central processing unit, the graphic processing unit and the expansion card are disposed on the motherboard. When the computer is in operation, the central processing unit is responsible for processing various data, and the graphic processing unit is responsible for processing image data, and both of which generate a lot of heat. Therefore, computer manufacturers generally install heat dissipation devices, such as air cooling or liquid cooling heat dissipation devices, to dissipate heat generated therefrom.

However, with the increasing amount of data to be processed and the demand for higher data processing speed, the heat dissipation efficiency of the existing air cooling or liquid cooling heat dissipation devices no longer meets the actual requirements. Therefore, how to further improve the heat dissipation efficiency of the heat dissipation device has become one of the crucial topics in this field.

### SUMMARY OF THE INVENTION

The invention is to provide an electronic device and a heat dissipation assembly which are capable of achieving an efficient heat dissipation.

One embodiment of the invention provides a heat dissipation assembly. The heat dissipation assembly is configured to be thermally coupled to a heat source. The heat dissipation assembly includes a thermoelectric cooler and a heat dissipation component. The thermoelectric cooler has a cold surface and a hot surface. The cold surface faces away from the hot surface, and the cold surface is configured to be thermally coupled to the heat source. The heat dissipation component is thermally coupled to the hot surface of the thermoelectric cooler.

Another embodiment of the invention provides an electronic device. The electronic device includes a heat source, a thermoelectric cooler, and a heat dissipation component. The thermoelectric cooler has a cold surface and a hot surface. The cold surface faces away from the hot surface, and the cold surface is thermally coupled to the heat source. The heat dissipation component is thermally coupled to the hot surface of the thermoelectric cooler.

Still another embodiment of the invention provides a heat dissipation assembly. The heat dissipation assembly is configured to be thermally coupled to a heat source. The heat dissipation assembly includes a first heat dissipation component and a second heat dissipation component. The first heat dissipation component has a cold surface and a hot surface. The cold surface faces away from the hot surface, and the cold surface is configured to be thermally coupled to the heat source. The second heat dissipation component is thermally coupled to the hot surface of the first heat dissipation component. A heat dissipation efficiency of the first heat dissipation component is greater than a heat dissipation efficiency of the second heat dissipation component.

According to the electronic device and the heat dissipation assembly disclosed in the above embodiments, the thermoelectric cooler is disposed between the heat source and the heat dissipation component, such that the thermoelectric cooler can rapidly cool the heat source, and heat generated by the thermoelectric cooler can be efficiently transferred to the outside via the heat dissipation component.

In addition, the heat dissipation efficiency of the thermoelectric cooler is greater than the heat dissipation efficiency of the heat dissipation component, and the thermoelectric cooler is eco-friendly and has small thermal inertia. Therefore, in a case that heat produced by the thermoelectric cooler is efficiently transferred to outside and there is no load on the cold surface of the thermoelectric cooler, the thermoelectric cooler can achieve a maximum temperature difference between the cold surface and the hot surface in a short time (e.g., less than one minute). Accordingly, the heat dissipation assembly can achieve multiple cooling, so as to achieve the efficient heat dissipation, and a higher-temperature working fluid can be used to take away the heat produced by thermoelectric cooler for reducing the power consumption.

Furthermore, the requirement to the surface area of the heat dissipation component can be reduced, such that the size of the heat dissipation component can be reduced to occupy less space while achieving the same heat dissipation effect, the manufacturing process of the heat dissipation component can be simplified, and the heat dissipation component can be massively manufactured. As a result, the heat dissipation assembly can satisfy the requirement of low cost and high performance so as to have a broad application prospect.

### BRIEF DESCRIPTION OF THE DRAWINGS

The present invention will become more fully understood from the detailed description given hereinbelow and the accompanying drawings which are given by way of illustration only and thus are not limitative of the present invention and wherein:

FIG. 1 is a side view of an electronic device according to one embodiment of the invention; and

FIG. 2 is an exploded view of the electronic device in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present invention, such as technical and scientific terms, have its own meanings and can be comprehended by those skilled in the art, unless the terms are additionally defined in the present invention. That is, the terms used in the following paragraphs should be read on the meaning commonly used in the related fields and will not be overly explained, unless the terms have a specific meaning in the present invention.

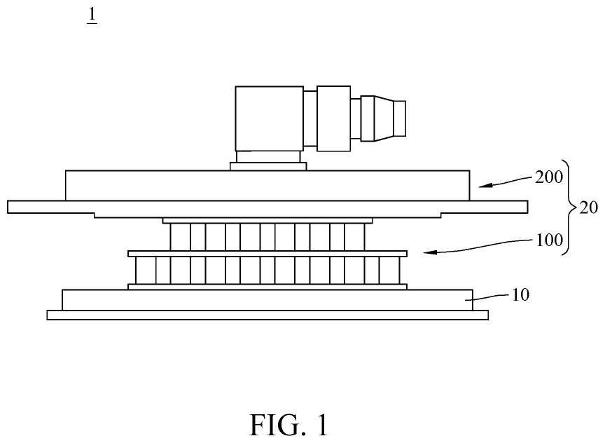

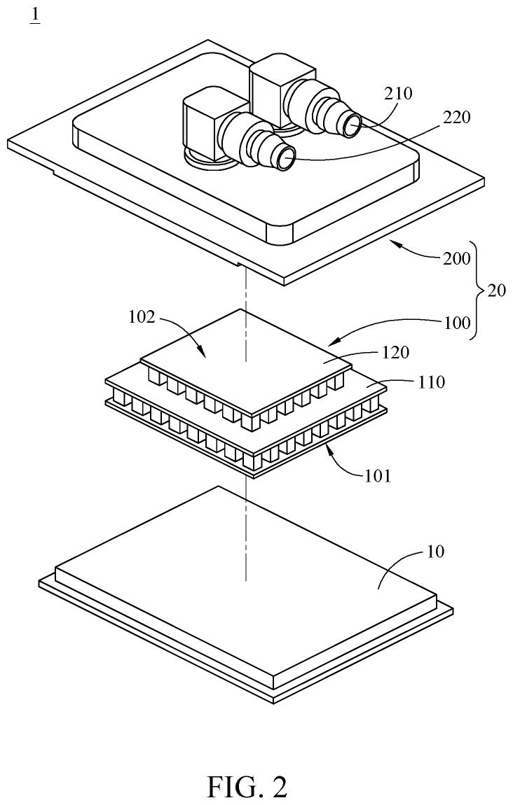

Referring to FIGS. 1 and 2, there are shown a side view of an electronic device 1 according to one embodiment of the invention and an exploded view of the electronic device 1 in FIG. 1.

In this embodiment, the electronic device 1 includes a heat source 10 and a heat dissipation assembly 20. The heat source 10 is, for example, a central processing unit or a graphic processing unit. The heat dissipation assembly 20 includes a thermoelectric cooler 100 and a heat dissipation component 200. The thermoelectric cooler 100 is, for example, a semiconductor thermoelectric cooler. The operation of the semiconductor thermoelectric cooler is based on Peltier effect; that is, when a direct current is applied on a circuit formed by two different electrically conductive materials, one joint releases Joule heat and other types of heat, while another joint absorbs heat. The aforementioned phenomenon can be reversed by reversing the applying direction of the direct current; that is, which joint is used to release heat and which joint is used to absorb heat can be determined by the applying direction of the direct current. The amount of heat absorbed and released by the joints is proportional to the intensity of the direct current, and is related to the properties of the conductive materials and the temperature of the hot end (or hot surface).

The thermoelectric cooler 100 has a cold surface 101 and a hot surface 102. The cold surface 101 faces away from the hot surface 102. The cold surface 101 is thermally coupled to the heat source 10. Specifically, the thermoelectric cooler 100 includes a first layer part 110 and a second layer part 120. The second layer part 120 is stacked on the first layer part 110, and the cold surface 101 and the hot surface 102 are respective located at the first layer part 110 and the second layer part 120. A transverse cross-sectional area of the first layer part 110 is greater than a transverse cross-sectional area of the second layer part 120. The first layer part 110 is configured to be in thermal contact with the heat source 10. The heat dissipation component 200 is in thermal contact with the second layer part 120.

The heat dissipation component 200 is thermally coupled to the hot surface 102 of the thermoelectric cooler 100. The heat dissipation component 200 is configured to dissipate the heat produced by the thermoelectric cooler 100 to the outside. The heat dissipation component 200 is, for example, a water block that is a liquid cooling heat dissipation component. The heat dissipation component 200 has a liquid inlet 210 and a liquid outlet 220. The liquid inlet 210 and the liquid outlet 220 are configured to be in fluid communication with each other via a pump, radiator and one or more pipes, such that the heat dissipation component 200, the pump, and the radiator together form a cooling loop.

The pump can drive a working fluid, such as water or a refrigerant, to flow in the cooling loop, such that heat produced by the thermoelectric cooler 100 can be transferred to the radiator via the working fluid, and then the radiator can transfer such heat to the outside.

In this embodiment, a thermally conductive gel (not shown) may be provided between the heat dissipation component 200 and the thermoelectric cooler 100 for reducing the thermal resistance between the heat dissipation component 200 and the thermoelectric cooler 100.

In this embodiment, the thermoelectric cooler 100 is disposed between the heat source 10 and the heat dissipation component 200, such that the thermoelectric cooler 100 can rapidly cool the heat source 10, and heat generated by the thermoelectric cooler 100 can be efficiently transferred to the outside via the heat dissipation component 200. The heat dissipation efficiency of the thermoelectric cooler 100 is greater than the heat dissipation efficiency of the heat dissipation component 200, and the thermoelectric cooler 100 is eco-friendly and has small thermal inertia. Therefore, in a case that heat produced by the thermoelectric cooler 100 is efficiently transferred to outside and there is no load on the cold surface 101 of the thermoelectric cooler 100, the thermoelectric cooler 100 can achieve a maximum temperature difference between the cold surface 101 and the hot surface 102 in a short time (e.g., less than one minute). Accordingly, the thermoelectric cooler 100 can cool the heat source 10, and the heat dissipation component 200 can transferred heat produced by the thermoelectric cooler 100 away, such that the cooperation of the thermoelectric cooler 100 and the heat dissipation component 200 achieve the efficient heat dissipation, and a higher-temperature working fluid can be used to take away the heat produced by thermoelectric cooler 100 for reducing the power consumption. In addition, the requirement to the surface area of the heat dissipation component 200 can be reduced, such that the manufacturing process of the heat dissipation component 200 can be simplified, and the heat dissipation component 200 can be massively manufactured. As a result, the heat dissipation assembly can satisfy the requirement of low cost and high performance so as to have a broad application prospect.

The thermoelectric cooler 100 of this embodiment has a wide range of applications, and the temperature difference of the thermoelectric cooler 100 can range from 90° C. to −130° C., which can cool the heat source 10 more effectively. Therefore, since the thermoelectric cooler 100 of the embodiment has a wide range of applications, the thermoelectric cooler 100 can be applied to the heat sources of different powers, especially a high-power heat source.

Note that the configuration of the heat dissipation assembly can be modified as required; in some other embodiments, the heat dissipation assembly may be thermally coupled to a heat source, and the heat dissipation assembly may include a first heat dissipation component and a second heat dissipation component, where the first heat dissipation component may have a cold surface and a hot surface facing away from the cold surface, the cold surface may be configured to be thermally coupled to the heat source, the second heat dissipation component may be thermally coupled to the hot surface of the first heat dissipation component, and the heat dissipation efficiency of the first heat dissipation component is greater than the heat dissipation efficiency of the second heat dissipation component.

According to the electronic device and the heat dissipation assembly disclosed in the above embodiments, the thermoelectric cooler is disposed between the heat source and the heat dissipation component, such that the thermoelectric cooler can rapidly cool the heat source, and heat generated by the thermoelectric cooler can be efficiently transferred to the outside via the heat dissipation component.

In addition, the heat dissipation efficiency of the thermoelectric cooler is greater than the heat dissipation efficiency of the heat dissipation component, and the thermoelectric cooler is eco-friendly and has small thermal inertia. Therefore, in a case that heat produced by the thermoelectric cooler is efficiently transferred to outside and there is no load on the cold surface of the thermoelectric cooler, the thermoelectric cooler can achieve a maximum temperature difference between the cold surface and the hot surface in a short time (e.g., less than one minute). Accordingly, the heat dissipation assembly can achieve multiple cooling, so as to achieve the efficient heat dissipation, and a higher-temperature working fluid can be used to take away the heat produced by thermoelectric cooler for reducing the power consumption.

Furthermore, the requirement to the surface area of the heat dissipation component can be reduced, such that the size of the heat dissipation component can be reduced to occupy less space while achieving the same heat dissipation effect, the manufacturing process of the heat dissipation component can be simplified, and the heat dissipation component can be massively manufactured. As a result, the heat dissipation assembly can satisfy the requirement of low cost and high performance so as to have a broad application prospect.

It will be apparent to those skilled in the art that various modifications and variations can be made to the present invention. It is intended that the specification and examples be considered as exemplary embodiments only, with a scope of the invention being indicated by the following claims and their equivalents.

What is claimed is:

1. A heat dissipation assembly, configured to be thermally coupled to a heat source, the heat dissipation assembly comprising:
a thermoelectric cooler, having a cold surface and a hot surface, wherein the cold surface faces away from the hot surface, and the cold surface is configured to be thermally coupled to the heat source; and
a heat dissipation component, thermally coupled to the hot surface of the thermoelectric cooler.

2. The heat dissipation assembly according to claim 1, wherein the thermoelectric cooler is a semiconductor thermoelectric cooler.

3. The heat dissipation assembly according to claim 2, wherein the thermoelectric cooler comprises a first layer part and a second layer part, the second layer part is stacked on the first layer part, a transverse cross-sectional area of the first layer part is greater than a transverse cross-sectional area of the second layer part, the first layer part is configured to be in thermal contact with the heat source, and the heat dissipation component is in thermal contact with the second layer part.

4. The heat dissipation assembly according to claim 1, wherein the heat dissipation component is a liquid cooling heat dissipation component.

5. An electronic device, comprising:
a heat source;
a thermoelectric cooler, having a cold surface and a hot surface, wherein the cold surface faces away from the hot surface, and the cold surface is thermally coupled to the heat source; and
a heat dissipation component, thermally coupled to the hot surface of the thermoelectric cooler.

6. The electronic device according to claim 5, wherein the heat source is a central processing unit or a graphic processing unit.

7. The electronic device according to claim 5, wherein the thermoelectric cooler is a semiconductor thermoelectric cooler.

8. The electronic device according to claim 7, wherein the thermoelectric cooler comprises a first layer part and a second layer part, the second layer part is stacked on the first layer part, a transverse cross-sectional area of the first layer part is greater than a transverse cross-sectional area of the second layer part, the first layer part is in thermal contact with the heat source, and the heat dissipation component is in thermal contact with the second layer part.

9. The electronic device according to claim 5, wherein the heat dissipation component is a liquid cooling heat dissipation component.

10. A heat dissipation assembly, configured to be thermally coupled to a heat source, comprising:
a first heat dissipation component, having a cold surface and a hot surface, wherein the cold surface faces away from the hot surface, and the cold surface is configured to be thermally coupled to the heat source; and
a second heat dissipation component, thermally coupled to the hot surface of the first heat dissipation component, wherein a heat dissipation efficiency of the first heat dissipation component is greater than a heat dissipation efficiency of the second heat dissipation component.
